(19) United States
(12) Patent Application Publication
(10) Pub. No.: US 2004/0245623 A1
(43) Pub. Date: Dec. 9, 2004

(54) Semiconductor device, circuit substrate and electronic instrument

(76) Inventors: Kazumi Hara, Suwa-shi (JP); Yoshihiko Yokoyama, Chino-shi (JP); Ikuya Miyazawa, Matsumoto-shi (JP); Koji Yamaguchi, Suwa-shi (JP)

Correspondence Address: HARNESS, DICKEY & PIERCE, P.L.C., P.O. BOX 828, BLOOMFIELD HILLS, MI, 48303, US

(21) Appl. No.: 10/794,783

(22) Filed: Mar. 5, 2004

(30) Foreign Application Priority Data
Mar. 28, 2003 (JP) 2003-091045

(51) Int. Cl. H01L 23/48

(52) U.S. Cl. 257/698; 257/700; 257/737

(57) ABSTRACT

A semiconductor device includes a semiconductor substrate with a through hole formed therein, a first insulating film formed inside the through hole, and an electrode formed on an inner side of the first insulating film inside the through hole. The first insulating film at the rear surface side of the semiconductor substrate protrudes beyond the rear surface, and the electrode protrudes on both the active surface side and the rear surface side of the semiconductor substrate. An outer diameter of a protruding portion on the active surface side is larger than an outer diameter of the first insulating film inside the through hole, and a protruding portion on the rear surface side protrudes further beyond the first insulating film to have a side surface thereof exposed. The semiconductor device has improved connectivity and connection strength and, in particular, has excellent resistance to shearing force when used in three-dimensional packaging technology.

### BACKGROUND OF THE INVENTION

1. Field of the Invention

Priority is claimed on Japanese Patent Application No. 2003-91045, filed Mar. 28, 2003, the content of which is incorporated herein by reference.

The present invention relates to a semiconductor device, a circuit substrate, and an electronic instrument.

2. Description of Related Art

In accompaniment to the demands for smaller sizes and lighter weights in portable electronic instruments such as mobile telephones, notebook computers, and personal digital assistants (PDA), attempts are being made to reduce the size of various types of electronic component such as semiconductor chips that are provided inside a portable electronic instrument. For example, innovations in packaging methods of semiconductor chips have been attempted and, currently, microminiature packaging known as chip scale packaging (CSP) is provided. The package surface area of semiconductor chips manufactured using this CSP technology is substantially the same as the surface area of the semiconductor chip, therefore, high density packaging can be achieved.

Accordingly, because there is a continuing trend demanding still smaller sizes and yet more functions in these electronic instruments, it is necessary to increase the packaging density of semiconductor chips even further. With this background, recent years have seen the development of three-dimensional packaging technology. This three-dimensional packaging technology is a technology that achieves high density semiconductor chip packaging by stacking together semiconductor chips having the same functions or semiconductor chips having different functions and then connecting each semiconductor chip together by wiring (see Japanese Patent Application Unexamined Publication (JP-A) No. 2001-53218).

In this three-dimensional packaging technology, when stacking a plurality of semiconductor chips, the wiring connections between the semiconductor chips are made by bonding together electrodes formed so as to penetrate substrates of the semiconductor chips using a brazing material such as solder.

However, in this three-dimensional packaging technology, although one side of a penetrating electrode is made to protrude from the semiconductor substrate so as to function as a bump, the other side of the electrode is simply formed with the same outer diameter as the protruding portion of the one side of the electrode. Therefore, when these electrodes are connected by a bonding material, the problem has arisen that it has not been possible to obtain excellent connectivity and connection strength.

The present invention was conceived in view of the above circumstances and it is an object thereof to provide a semiconductor device that has improved connectivity and connection strength and, in particular, has excellent resistance to shearing force used in three-dimensional packaging technology in which semiconductor devices are stacked in order to achieve high density packaging, particularly when one side of a penetrating electrode is bonded by a brazing material such as solder to an opposite side of another penetrating electrode, and also to provide a circuit substrate and an electronic instrument that are provided with this semiconductor device.

### SUMMARY OF THE INVENTION

In order to achieve the above object, according to an aspect of the present invention, there is provided a semiconductor device comprising: a semiconductor substrate with a through hole formed therein; a first insulating film formed on an inner wall of the through hole; and an electrode formed on an inner side of the first insulating film inside the through hole, wherein the first insulating film at a rear surface side of the semiconductor substrate protrudes beyond the rear surface, and the electrode protrudes on both an active surface side and the rear surface side of the semiconductor substrate, and an outer diameter of a protruding portion of the electrode on the active surface side is larger than an outer diameter of the first insulating film inside the through hole, and a protruding portion of the electrode on the rear surface side protrudes further beyond the first insulating film so as to have a side surface thereof exposed.

According to this semiconductor device, the electrode that protrudes from both the active surface side and the rear surface side of a semiconductor substrate is formed such that the protruding portion on the active surface side has a larger outer diameter than the outer diameter of the first insulating film that is inside the through hole, and also such that the protruding portion on the rear surface side protrudes further beyond the first insulating film and side surfaces thereof are in an exposed state. Therefore, when stacking the semiconductor devices, wiring connections between these semiconductor devices are easily made by bonding brazing material to protruding portions of the respective electrodes.

Moreover, because the protruding portion on the active surface side, in particular, is formed having a larger outer diameter than the outer diameter of the first insulating film inside the through hole, brazing material is more easily bonded to outer surface of this, and the bond strength of the outer surface with the bonded brazing material is great. On the other hand, because the protruding portion on the rear surface side protrudes still further beyond the first insulating film such that side surfaces thereof are in an exposed state, brazing material bonds more easily to the protruding, exposed side surfaces. Accordingly, brazing material easily bonds both to the protruding portion on the active surface side and to the protruding portion on the rear surface side. Therefore, when stacking semiconductor devices, if wiring connections between the electrodes are made using brazing material, the brazing material is more excellently bonded to the electrodes, resulting in a stack structure that has excellent bond strength being formed.

According to another aspect of the present invention, there is provided a semiconductor device comprising: a plurality of the above semiconductor devices that are stacked vertically with an active surface side of one semiconductor substrate facing a rear surface side of another semiconductor substrate, wherein a protruding portion of an electrode of one semiconductor device of the plurality of semiconductor devices is electrically connected by brazing material to a protruding portion of an electrode of another semiconductor device of the plurality of semiconductor devices, and wherein the brazing material forms a fillet that bonds from an outer surface of the protruding portion of the electrode of the one semiconductor device on the active surface side of the one semiconductor substrate to a side surface of the protruding portion of the electrode of the another semiconductor device on the rear surface side of the another semiconductor substrate, the side surface protruding beyond the first insulating film and being exposed.

With the structure as described above, as is described above, brazing material easily bonds both to the protruding portion on the active surface side and to the protruding portion on the rear surface side. Therefore, brazing material bonds better to the electrodes and forms a fillet. As a result, a stacked structure that has excellent bond strength and has excellent resistance to shearing force, in particular, is formed.

Preferably, the above described semiconductor device further comprises a second insulating film that covers at least peripheral portions of the electrode on the rear surface side of the semiconductor substrate, and the electrode protrudes beyond the second insulating film such that at least a portion of a side surface of the electrode is exposed.

With the structure as described above, even if the bonding material that bonds electrodes together is deformed when stacking a plurality of semiconductor devices, because the second insulating film insulates the bonding material from the rear surface of the semiconductor substrate, the bonding material does not directly touch the rear surface of the semiconductor substrate, thereby preventing short circuits from occurring between the two.

Preferably, the above described semiconductor device further comprises a barrier layer provided between the first insulating film and the electrode such that electrode material is prevented from spreading to the semiconductor substrate.

With the structure as described above, if copper, in particular, is used for the electrode material, it is possible to prevent the copper from spreading onto the semiconductor substrate during the formation of the electrode, and, accordingly, to maintain the excellent characteristics of the semiconductor device.

According to a further aspect of the present invention, there is provided a circuit substrate comprising the above described semiconductor device.

According to this circuit substrate, because a semiconductor device that has a high packaging density is provided, a reduction in both size and weight can be achieved, and the wiring connections are extremely reliable.

According to a still another aspect of the present invention, there is provided an electronic instrument comprising the above described semiconductor device.

According to this electronic instrument, because a semiconductor substrate that has a high packaging density is provided, a reduction in both size and weight can be achieved, and the wiring connections are extremely reliable.

### BRIEF DESCRIPTION OF THE DRAWINGS

FIG. 1 is an enlarged view of the principal portions of an embodiment of the semiconductor device of the present invention.

FIGS. 2A to 2C are explanatory views of a manufacturing process of the semiconductor device shown in FIG. 1.

FIGS. 3A and 3B are explanatory views of a manufacturing process of the semiconductor device shown in FIG. 1.

FIGS. 4A and 4B are explanatory views of a manufacturing process of the semiconductor device shown in FIG. 1.

FIGS. 5A and 5B are explanatory views of a manufacturing process of the semiconductor device shown in FIG. 1.

FIGS. 6A to 6C are explanatory views of a manufacturing process of the semiconductor device shown in FIG. 1.

FIG. 7 is a side cross-sectional view showing a semiconductor device that has been three-dimensionally packaged.

FIG. 8 is an enlarged view of principal portions of FIG. 7.

FIG. 9 is a schematic structural view of an embodiment of the circuit substrate of the present invention.

FIG. 10 is a schematic structural view of an embodiment of the electronic instrument of the present invention.

### DETAILED DESCRIPTION OF THE INVENTION

The present invention will now be described in detail.

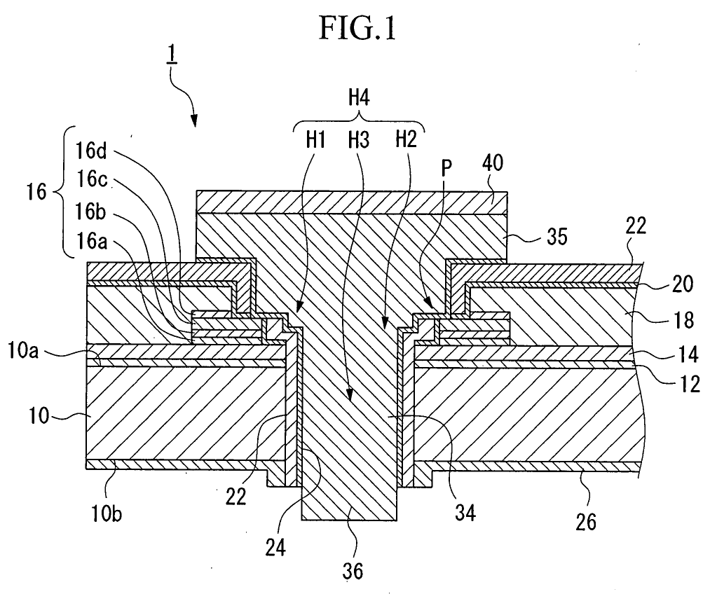

FIG. 1 is a view of the principal portions of an embodiment of the semiconductor device of the present invention. The symbol 1 in FIG. 1 is a semiconductor device (i.e., a semiconductor chip). This semiconductor device 1 has a semiconductor substrate 10 formed from silicon and an electrode 34 provided via a first insulating film 22 inside a through hole H4 formed in the semiconductor substrate 10. Here, the through hole H4 is formed penetrating from an active surface 10a side of the semiconductor substrate 10 towards a rear surface 10b side thereof.

On the active surface 10a side of the semiconductor substrate 10 is formed an integrated circuit (not shown) formed by transistors and memory devices and by other electronic devices. An insulating film 12 is formed on the surface of the active surface 10a, and an interlayer insulating film 14 formed from borophosphosilicate glass (BPSG) is further formed on top of the insulating film 12.

An electrode pad 16 is formed at a predetermined location on a surface of the interlayer insulating film 14. The electrode pad 16 is formed by stacking in the following order a first layer 16a formed from titanium (TI) or the like, a second layer 16b formed from titanium nitride (TiN) or the like, a third layer 16c formed from aluminum/copper (AlCu) or the like, and a fourth layer (i.e., a capping layer) 16d formed from TiN or the like. Note that the component materials of the electrode pad 16 may be appropriately selected in accordance with the electrical characteristics, physical characteristics, and chemical characteristics required by the electrode pad 16. For example, it is possible to form the electrode pad 16 using only Al that is typically used for electrodes for integration, or to form the electrode pad 16 using only copper that has low electrical resistance.

Here, the electrode pad 16 is formed arranged in a peripheral portion of the semiconductor device 1, or is formed arranged in a center portion of the semiconductor device 1, and an integrated circuit is not formed below the electrode pad 16. A passivation film 18 is formed on a surface of the interlayer insulating film 14 so as to cover the electrode pad 16. The passivation film 18 is formed from silicon oxide, silicon nitride or a polyimide resin or the like, and may have a thickness of, for example, 1 μm.

An aperture portion H1 of the passivation film 18 is formed in a center portion of the electrode pad 16, and an aperture portion H2 is also formed in the electrode pad 16. Note that an inner diameter of the aperture portion H2 is smaller than an inner diameter of the aperture portion H1 and is, for example, approximately 60 μm. An insulating film 20 formed from SiO₂ or the like is formed on a surface of the passivation layer 18 as well as on inner surfaces of the aperture portion H1 and the aperture portion H2. By employing a structure such as this, a hole portion H3 that penetrates the insulating film 20, the interlayer insulating film 14, the insulating film 12, and the semiconductor substrate 10 is formed in the center portion of the electrode pad 16. An inner diameter of the hole portion H3 is smaller than an inner diameter of the aperture portion H2 and is, for example, approximately 30 μm. Note that in the present embodiment the hole portion H3 has a circular configuration when seen in plan view, however, the configuration is not limited to this and it may also be a rectangular configuration when seen in plan view.

A first insulating film 22 formed from SiO₂ or the like is formed on an inner wall surface of the hole portion H3 and on a surface of the insulating film 20. The purpose of the first insulating film 22 is to prevent the occurrence of current leaks and corrosion and the like caused by oxygen and moisture and, in the present embodiment, is formed having a thickness of approximately 1 μm. Moreover, one end of the first insulating film 22 is made to protrude from the rear surface 10b of the semiconductor substrate 10, particularly on the side thereof that covers the inner wall surface of the hole portion H3.

The insulating film 20 formed on a surface of the third layer 16c of the electrode pad 16 and the first insulating film 22 are partially removed along the circumference of the aperture portion H2. A backing film 24 is formed on the exposed surface of the third layer 16c of the electrode pad 16 and the exposed surface (i.e., an inner surface) of the first insulating layer 22. The backing film 24 is formed by a barrier layer (i.e., a barrier metal) formed on a surface (the inner surface) of the first insulating layer 22 and the like, and a seed layer (i.e., a seed electrode) formed on a surface (i.e., inner surface) of the barrier layer. The purpose of the barrier layer is to prevent electroconductive material used to form the electrode 34 (described below) from scattering onto the semiconductor substrate 10, and is formed from titanium tungsten (TiW) or titanium nitride (TiN) or the like. The seed layer is an electrode used when the electrode 34 (described below) is formed by plating processing, and is formed from Cu and Au, or Ag and the like.

The electrode 34 that is formed from an electroconductive material having low electrical resistance such as Cu, W, or the like is formed inwardly of the backing film 24, in a state of being embedded in the through hole portion H4 formed by the aperture portion H2 and the hole portion H3. As the electroconductive material used to form the electrode 34 a material obtained by doping an impurity such as boron (B) or phosphorus (P) in polysilicon. In this case, because there is no longer any need to prevent metal from scattering onto the semiconductor substrate 10, the aforementioned barrier layer can be done away with.

The electrode 34 and the electrode pad 16 are electrically connected at the position P in FIG. 1, and a portion formed inside the hole portion H3 in the electrode 34 becomes a plug portion 36. A bottom end portion of the plug portion 36, namely, an end portion on the rear surface 10b side of the semiconductor substrate 10 protrudes beyond the rear surface 10b of the semiconductor substrate 10. In addition, an end surface of this bottom end portion is exposed to the outside. Note that, as is described above, the first insulating film 22 is positioned surrounding the plug portion 36 (i.e., the electrode 34) in the through hole H4, and one end of the first insulating film 22 also protrudes beyond the rear surface 10b of the semiconductor substrate 10. However, the plug portion 36 is formed protruding even further towards the outside than the protruding first insulating layer 22.

In contrast, on the active surface 10a side of the semiconductor substrate 10, a post portion 35 of the electrode 34 is formed on the first insulating film 22 at a peripheral portion of the aperture portion H1. This post portion 35 is formed having a larger outer diameter than the outer diameter of the first insulating film 22 that protrudes on the rear surface 10b side, and, in the present embodiment, is formed having a circular configuration or having a square configuration when seen in plan view. In addition, a brazing material layer 40 is formed on top of the post portion 35. The brazing material layer 40 is formed by solder or the like, which is a soft brazing material, and, specifically, is formed by tin/silver, lead-free solder, metal paste or molten paste. Note that the term “solder” here refers also to lead-free solder.

Here, the length that the plug portion 36 protrudes beyond the first insulating film 22 is set at between 2 and 20% of the length of the electrode 34, specifically, between approximately 10 and 20 μm. By making the plug portion 36 protrude this far, when a plurality of semiconductor devices 1 are stacked and the electrodes 34 are connected by brazing using the brazing material 40, as is described below, the brazing material flows excellently on the exposed side surface of the protruding plug portion 36 and bonds excellently to this spot. As a result, excellent adhesiveness is obtained. In addition, a sufficient gap is formed between stacked upper and lower semiconductor devices 1, resulting in the filling in of underfill and the like being simplified. By adjusting the length of the protrusion of the plug portion 36 it is possible to appropriately adjust the gap between stacked semiconductor devices 1. Moreover, instead of filling in underfill and the like after the stacking, the connection of the wiring of the semiconductor device 1 can be reliably performed by applying the thermosetting resin coating while avoiding the protruding plug portions 36, even in cases when thermosetting resin or the like is coated on the rear surface 10b of the semiconductor device 1 before stacking.

A second insulating film 26 is formed on the rear surface 10b of the semiconductor substrate 10. Because the second insulating film 26 is formed from silicon oxide, silicon nitride, or polyimide resin or the like, it is formed over substantially the entire rear surface 10b except for the interior of the through hole H4 that opens onto the rear surface 10b. Note that the second insulating film 26 may also be formed only around the periphery of the electrode 34, namely, instead of covering the entire rear surface 10b, the second insulating film 26 may be formed only around the periphery of the through hole H4.

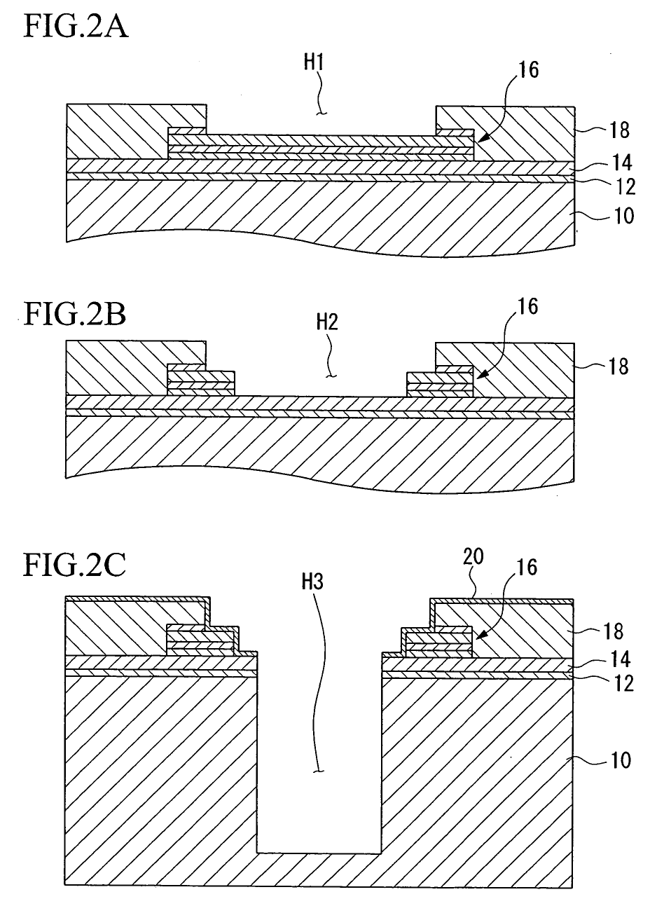

Next, a process to manufacture this type of semiconductor substrate 1 will be described using FIGS. 2 to 6. Note that the description below applies to cases in which processing is performed to simultaneously form a large number of semiconductor devices on multiple, large scale semiconductor substrates (referred to below simply as “substrate 10”), however, it is to be understood that the present invention also applies when manufacturing semiconductor devices on single, small size substrates.

Firstly, as is shown in FIG. 2A, the insulating film 12 and the interlayer insulating film 14 are formed on the surface of the substrate 10. Next, an electrode pad 16 is formed on the surface of the interlayer insulating film 14. When forming the electrode pad 16, firstly the first layer 16a through to the fourth layer 16d of the electrode pad 16 are formed in that sequence on the entire surface of the interlayer insulating film 14 by sputtering or the like. Next, a resist layer is formed, and this is then patterned by photolithographic technology to form a resist pattern. Next, etching is performed using the resist pattern as a mask, so as to form an electrode pad in a predetermined configuration (for example, a rectangular configuration).

Next, the passivation film 18 is formed on the surface of the electrode pad 16, and an aperture portion H1 is then formed in the passivation film 18. Specifically, firstly, a resist film is formed over the entire surface of the passivation film 18. Any one of photo resist, electron beam resist, or X-ray resist may be used for the resist, and it may be either a positive type or negative type. The method used to apply the resist coating may be selected appropriately from a spin coating method, a dipping method, or a spray coating method. Using a mask on which the aperture portion H1 pattern has been formed, exposure processing is performed on the resist film, and then developing processing is performed thereon. As a result, a resist pattern having the configuration of the aperture portion H1 is formed. Note that after the resist has been patterned it is post baked to form the resist pattern.

Next, the passivation film 18 is etched using this resist pattern as a mask. Here, in the present embodiment, the fourth layer 16d of the electrode pad 16 is etched together with the passivation film 18. It is possible to use wet etching for the etching, however, it is more preferable that dry etching such as reactive ion etching (RIE) is used. After the aperture portion H1 has been formed in the passivation film 18, the resist on the passivation film 18 is peeled off using a peeling solution. As a result, as is shown in FIG. 2A, the aperture portion H1 is formed in the passivation film 18, thereby exposing the electrode pad 16.

Next, as is shown in FIG. 2B, the aperture portion H2 is formed in the electrode pad 16. Specifically, firstly, a resist film is formed on the entire surface of the exposed electrode pad 16 and passivation film 18. Next, this is formed into a resist pattern having the configuration of the aperture portion H2. Next, using this resist pattern as a mask, the electrode pad 16 is dry etched. Here, RIE is preferably used as the dry etching method. Subsequently, the resist is peeled off resulting in the aperture portion H2 being formed in the electrode pad 16, as is shown in FIG. 2B.

Next, as is shown in FIG. 2C, the insulating film 20 is formed on the entire surface of the substrate 10. This insulating film 20 functions as a mask when the hole portion H3 is being formed by dry etching in the substrate 10. The thickness of the insulating film 20 differs depending on the depth of the hole portion H3 to be formed in the substrate 10, however, it may be set, for example, at 2 μm. In the present embodiment, SiO₂ is used for the insulating film 20, however, photo resist may also be used if a selection ration with Si can be obtained. When forming the insulating film 20, for example, a plasma enhanced chemical vapor deposition (PECVD) method, a thermal CVD method or the like may be employed.

Next, the shape of the hole portion H3 is patterned in the insulating film 20. Specifically, firstly, a resist film is formed on the entire surface of the insulating film 20, and the shape of the hole portion H3 is patterned on this. Next, the insulating film 20, the interlayer insulating film 14, and the insulating film 12 are dry etched using this resist pattern as a mask. Thereafter, by peeling off and removing the resist, the shape of the hole portion H3 is given to the insulating film 20 and the like and the substrate 10 is exposed.

Next, the hole of the hole portion H3 is opened up in the substrate 10 by high speed dry etching. As the dry etching method, RIE or inductively coupled plasma (ICP) can be used. At this time, as is described above, the insulating film 20 (SiO₂) is used as a mask, it is also possible to use a resist pattern as a mask instead of the resist film 20. Note that the depth of the hole portion H3 is set appropriate to the thickness of the semiconductor device that is ultimately formed. Namely, after the semiconductor device 1 has been etched to its ultimate thickness, the depth of the hole portion H3 is set such that the distal end portion of the electrode formed inside the hole portion H3 is exposed at the rear surface of the substrate 10. Accordingly, as is shown in FIG. 2C, the hole portion H3 can be formed in the substrate 10.

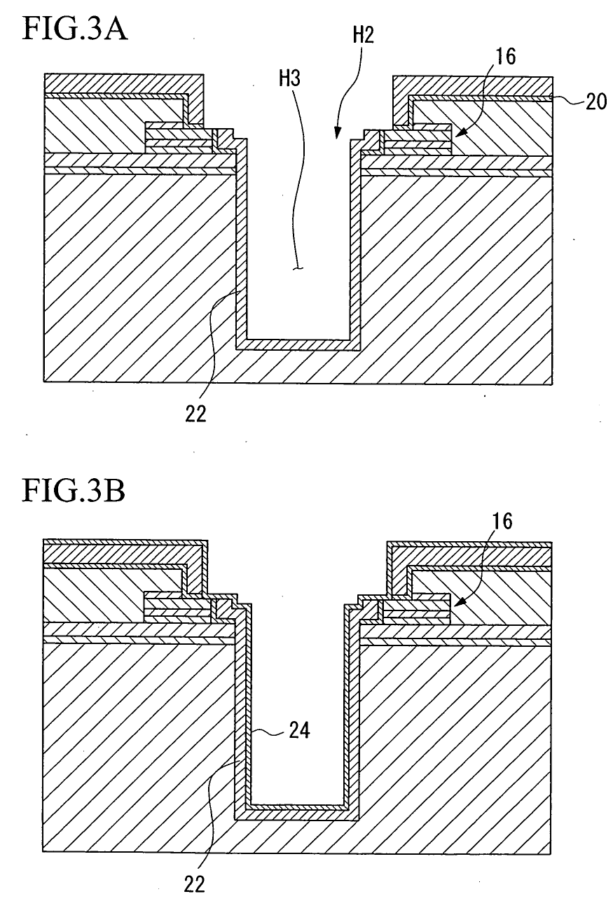

Next, as is shown in FIG. 3A, the first insulating film 22 is formed on the inner surface of the hole portion H3 and on the surface of the insulating film 20. The first insulating film 22 is formed, for example, by an SiO₂ film formed from tetraethoxysilane (TEOS), and is formed such that the film thickness at the surface on the active surface 10a side of the substrate 10 is approximately 1 μm.

Next, anisotropic etching is performed on the first insulating film 22 and the insulating film 20 so as to expose a portion of the electrode pad 16. Note that, in the present embodiment, a portion of the surface of the electrode pad 16 is exposed at peripheral portions of the aperture portion H2. Specifically, firstly, a resist film is formed on an entire surface of the first insulating film 22, and the exposed portion is patterned. Next, using this resist pattern as a mask, anisotropic etching is performed on the first insulating film 22 and on the insulating film 20. Dry etching such as RIE is preferably used for this anisotropic etching. As a result, the state shown in FIG. 3A is obtained.

Next, as is shown in FIG. 3B, the backing film 24 is formed on the surface of the exposed electrode pad 16 and on the surface of the first insulating film 22. As the backing film 24 a film obtained by first forming a barrier layer and then forming a seed layer on the barrier layer is used. The method used to form the barrier layer and the seed layer may be, for example, a physical vapor deposition (PVD) method such as vacuum deposition, sputtering, or ion plating, a CVD method, an ion metal plasma (IMP) method, or an electroless plating method.

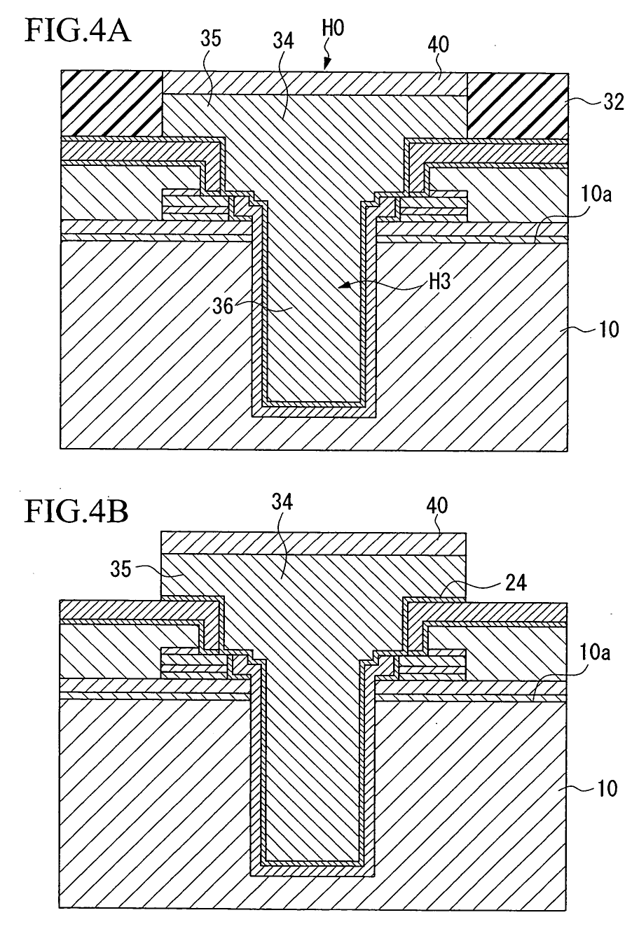

Next, as is shown in FIG. 4A, the electrode 34 is formed. Specifically, firstly, resist 32 is provided on an entire surface on the active layer 10a side of the substrate 10. Liquid resist used for plating or dry film or the like can be employed for the resist 32. Note that it is also possible to use resist that is used when etching an Al electrode that is typically formed in a semiconductor device, or resin resist that has insulating properties. However, in this case, these resists must have the capacity to resist the plating solution and etching solution used in the steps described below.

If a liquid resist is used for the formation of the resist 32, a spin coating method, dipping method, spray coating method, or the like can be employed. The thickness of the resist 32 being formed is substantially the same as the thickness of the brazing material layer 40 added to the height of the post portion 35 of the electrode 34 being formed.

Next, the planar configuration of the post portion 35 of the electrode 34 being formed is patterned on the resist. Specifically, the resist 32 is patterned by performing exposure processing and developing processing using a mask on which a predetermined pattern is formed. Here, if the planar configuration of the post portion 35 is circular, a circular aperture portion is patterned on the resist 32. If the planar configuration is rectangular, then a rectangular aperture portion is patterned on the resist 32. Because, in the present example, the aperture portion has a circular configuration, the size of this aperture portion is set such that the outer diameter thereof is larger than the outer diameter of the first insulating film 22 protruding on the rear surface 10b side (described below). If the aperture portion has, for example, a rectangular configuration, the external diameter thereof, namely, the sizes of the sides thereof are set such that the full surface configuration thereof completely covers the outer shape of the first insulating film 22 protruding on the rear surface 10b side.

Note that, in the above description, a method is described in which the resist 32 is formed such that the post portion 35 of the electrode 34 is enclosed, however, it is not absolutely necessary for the resist 32 to be formed in this manner, and the resist 32 may be formed appropriately in accordance with the configuration of the electrode 34. In addition, in the above description, the resist 32 is formed using photolithographic technology, however, if the resist 32 is formed using this method, then it is possible that, when the resist is being coated over the entire surface, a portion thereof may enter into the hole portion H3 and that this portion may remain inside the hole portion H3 as residue even when developing processing is performed. Therefore, as is described above, it is also possible to form the resist 32 in a patterned state by using dry film or by using a screen printing method. Moreover, it is also possible to selectively discharge droplets of resist only in resist formation positions using a droplet discharge method such as an inkjet method so as to form resist 32 that is already in a patterned state. By employing this method, the resist 32 can be formed without resist 32 entering into the hole portion H3.

Next, the electrode 34 is formed using this resist 32 as a mask. As a result, an electrode material (i.e., an electroconductive material) is embedded inside a concave portion H0 formed by the aperture portion H1, the aperture portion H2, and the hole portion H3, and the plug 36 is thereby formed. The electrode material is also embedded on the pattern formed on the resist 32 so as to form the post portion 35. A plating processing method or a CVD method or the like can be used for the embedding (i.e., for the filling in) of the electrode material (i.e., the electroconductive material), however, a plating processing method is particularly preferably used. An example of a preferably used plating processing method is an electrochemical plating (ECP) method. Note that the seed layer forming the backing film 24 can be used as an electrode in this plating processing method. Furthermore, a cup type of plating apparatus that provides plating by discharging plating solution from a container having a cup configuration can be used as the plating apparatus.

Next, the brazing material layer 40 is formed on the surface of the electrode 34. A solder plating method or a screen printing method or the like can be used for forming the brazing material layer 40. Note that the seed layer forming the backing film 24 can also be used as the solder plating electrode. In addition, a cup type of plating apparatus can be used as the plating apparatus. Solder (including lead free solder), which is a particularly soft brazing material, is preferably used as the brazing material. As a result of the above, the state shown in FIG. 4A is obtained.

Next, as is shown in FIG. 4B, using a peeling solution or the like, the resist 32 is peeled off and removed. Ozone water, for example, can be used as the peeling solution. Next, the backing film 24 exposed on the active surface 10a side of the substrate 10 is removed. Specifically, firstly, a resist film is formed on the entire surface on the active surface 10a side of the substrate 10. Next, this is patterned to the shape of the post portion 35 of the electrode 34. Next, using this resist pattern as a mask, the backing film 24 is dry etched. Note that if a brazing material other than solder is used for the brazing material layer 40, then, depending on the substance of this brazing material, this can be used as a mask and the manufacturing procedure can be simplified. As a result of the above, the state shown in FIG. 4B is obtained.

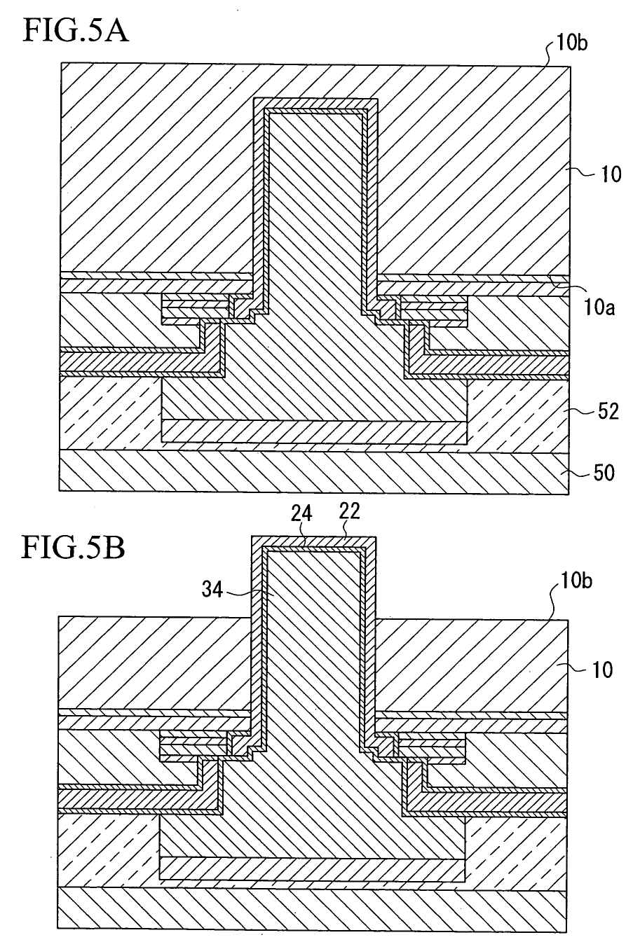

Next, as is shown in FIG. 5A, the substrate 10 is inverted vertically and a reinforcing member 50 is adhered to the active surface 10a side of the substrate 10 that, in this state, is on the bottom side. A soft material such as a resin film or the like can be used as the reinforcing member 50, however, it is preferable that a hard material such as glass or the like is used in order to provide mechanical reinforcement, in particular. By adhering a hard reinforcing member 50 such as this to the active surface 10a side of the substrate 10 it is possible to correct warping of the substrate 10 and, in addition, it is possible to prevent cracks from occurring in the substrate 10 when the rear surface 10b of the substrate 10 is being worked, or when the substrate 10 is being handled. An adhesive agent 52, for example, can be used to adhere the reinforcing member 50. An adhesive agent that is thermosetting or is photo-curing is preferably used as the adhesive agent 52. By using an adhesive agent such as this, the reinforcing member 50 can be firmly adhered to the substrate 10 while allowing bumps and indentations in the active surface 10 of the substrate 10 to be absorbed. In particular, if an ultraviolet-curing adhesive agent is used as the adhesive agent 52, it is preferable that a light transmitting material such as glass or the like is used for the reinforcing member 50. If this material is employed the adhesive agent 52 can be easily cured by irradiating light from the outside of the reinforcing member 50.

Next, as is shown in FIG. 5B, the entire rear surface 10b of the of the substrate 10 is etched so that the plug portion 36 of the electrode 34 is made to protrude beyond the rear surface 10b while still being covered by the first insulating film 22. Either wet etching or dry etching can be used for the etching at this time. If dry etching is used, then, for example, inductively coupled plasma (ICP) or the like can be used. Note that it is preferable that, prior to the etching, the rear surface 10b of the substrate 10 is polished (by rough polishing) until just before the first insulating film 22 or the electrode 34 is exposed, and then the etching is performed. By performing the procedure in this manner, the processing time can be shortened and productivity improved. It is also possible for the etching removal of the first insulating film 22 and the backing film 24 to be performed in the same step as the etching processing of the substrate 10. If the etching removal of the first insulating film 22 and the backing film 24 is performed in this manner, then wet etching using, for example, a mixed solution of hydrofluoric acid (HF) and nitric acid (HNO₃) as an etchant can be employed for the etching.

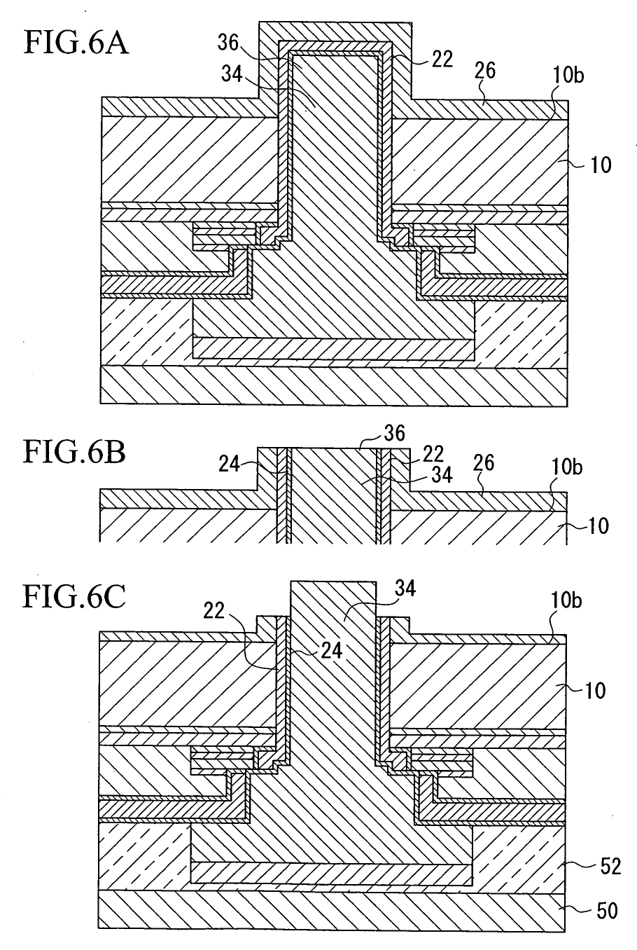

Next, as is shown in FIG. 6A, the second insulating film 26 that is formed from silicon oxide (SiO₂), silicon nitride (SiN), polyimide resin or the like is formed on the entire rear surface 10b of the substrate 10. If the second insulating film 26 is formed using silicon oxide and silicon nitride, a CVD method is preferably used. If the second insulating film 26 is formed using polyimide resin or the like, then it is preferable that the second insulating film is formed by coating by spin coating, and then drying and baking the resin. Naturally, the second insulating film 26 may also be formed using spin on glass (SOG).

It is also possible to not form the second insulating film 26 on the entire rear surface 10b of the substrate 10, but to form the second insulating film 26 only at peripheral portions of the electrode 34 on the rear surface 10b. In this case, for example, it is possible to selectively discharge a liquid insulating film material using a droplet discharge apparatus such as an inkjet apparatus onto peripheral portions of the electrode 34, and to then dry and bake the liquid insulating film material so as to form the first insulating film 26.

Next, as is shown in FIG. 6B, the second insulating film 26, the first insulating film 22, and the backing film 24 that cover an end surface of the plug portion 36 of the electrode 34 are selectively removed. This removal processing can be performed by dry etching or wet etching, however, it is preferable that it be performed using a chemical mechanical polishing (CMP) method, in particular, to polish the rear surface 10b side of the substrate 10. By performing this type of polishing, the second insulating film 26, the first insulating film 22, and the backing film 24 are removed in sequence by polishing, and the end surface of the plug portion 36 of the electrode 34 can be exposed.

Next, as is shown in FIG. 6C, the backing film 24, the first insulating film 22, and the second insulating film 26 that cover the side surface of the plug portion 36 of the electrode 34 are removed by etching. However, not all of the portions of these films covering the side surfaces of the plug 36 that are on the outside of the rear surface 10b of the substrate 10 are removed, instead a portion thereof is removed while allowing a portion to remain such that a portion of the electrode 34 that protrudes beyond the rear surface 10b is covered. In addition, it is necessary to set the etching conditions such that the entire thickness of the second insulating film 26 covering the rear surface 10b of the substrate 10 is not removed.

Dry etching or wet etching can be used for such etching. If dry etching is used, then, for example, reactive ion etching (RE) that uses CF₄ or O₂ as the gas is preferably used. If wet etching is used, then it is necessary to selectively remove only the second insulating film 26, the first insulating film 22, and the backing film 24 without encroaching into the Cu and W that are the material of the electrode 34. An example of an etchant that allows this type of selective removal to be performed is dilute hydrofluoric acid or a mixed solution of diluted hydrofluoric acid and diluted nitric acid. Note that because the second insulating film 26 covering the rear surface 10b is etched by this etching, it is preferable that the thickness of the second insulating film 26 is determined and the second insulating film 26 formed while predicting in advance the thickness of the etching.

Subsequently, the adhesive agent 52 on the active surface 10a side of the substrate 10 is dissolved by a solvent or the like, and the reinforcing member 50 is detached from the substrate 10. Depending on the type of adhesive agent 52, it may also be possible to detach the reinforcing member 50 by eliminating the adhesiveness (or viscosity) of the adhesive agent 52 by irradiating ultraviolet rays or the like onto it. Next, dicing tape (not shown) is adhered to the rear surface 10b of the substrate 10. By dicing the substrate 10 in this state, the semiconductor 1 can be separated into individual pieces. Note that the substrate 10 can be cut into pieces by irradiating a CO₂ laser or YAG laser onto it. As a result of the above, the semiconductor device 1 shown in FIG. 1 is obtained.

Note that in the semiconductor device 1 of the above described embodiment the second insulating film 26 is provided on the rear surface 10b of the semiconductor device 10, however, the present invention is not limited to this and it is also possible to form the rear surface 10b such that it is exposed. In this case too, because the electrode 34 is covered with the first insulating film 22 protruding beyond the rear surface 10b, in the brazing (i.e., the soldering) when stacking semiconductor devices 1, as is described below, it is possible to prevent the brazing material (i.e., the solder) from coming into contact with the rear surface 10b.

Next, a semiconductor device obtained by stacking semiconductor devices 1 obtained in the manner described above will be described.

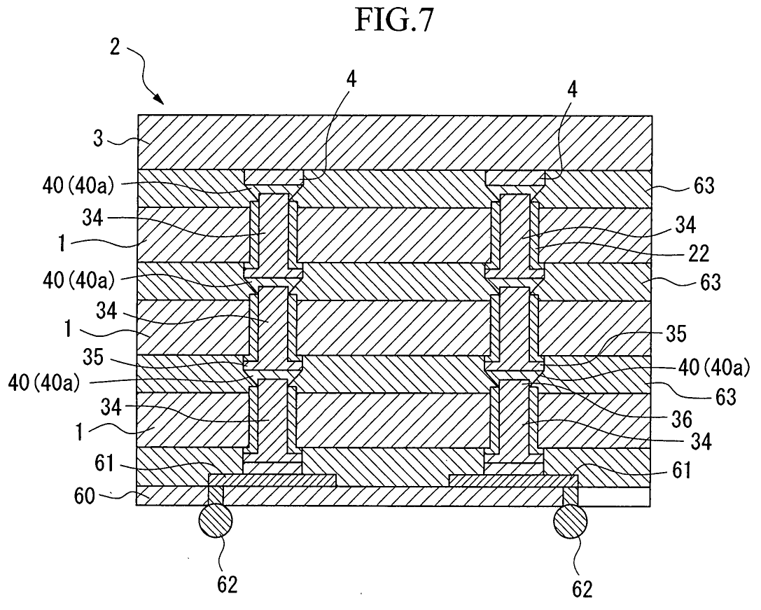

FIG. 7 is a diagram showing a three dimensionally packaged semiconductor device 2 obtained by stacking semiconductor devices 1. This semiconductor device 2 is formed by stacking a plurality (three in FIG. 7) of semiconductor devices 1 on an interposer substrate 60, and then stacking a different type of semiconductor device 3 on top of the semiconductor devices 1. Note that in this example a case is described in which the second insulating film 26 is not formed on the rear surface side of the semiconductor substrate 10, however, it is to be understood that a semiconductor device with the second insulating film 26 formed thereon may also be used.

Wiring 61 is formed on the interposer substrate 60, and solder balls 62 electrically connected to the wiring 61 are provided on a bottom surface of the interposer substrate 60. Semiconductor devices 1 are stacked via the wiring 61 on a top surface of the interposer substrate 60. Namely, in these semiconductor devices 1, post portions 35 of electrodes 34 protruding on the active surface 10a side thereof are joined to the wiring 61 via the brazing material layers 40 provided on top of the semiconductor devices 1, and by means of these the semiconductor devices 1 are stacked on top of the interposer substrate 60. Gaps between the interposer substrate 60 and the semiconductor devices 1 are filled with nonconductive underfill 63. As a result, not only are the semiconductor devices 1 fixed firmly on the interposer substrate 60, but insulation is provided between electrodes in locations other than the bond locations.

Moreover, in the semiconductor devices 1 that are stacked in sequence on top of this semiconductor device 1 as well, by bonding the respective post portions 35 via a brazing material layer 40 to the top of the plug portions 36 of the semiconductor device 1 underneath, and then filling in the gaps with underfill 63, each semiconductor device 1 is firmly fixed to the semiconductor device 1 underneath it. Furthermore, in this example, electrodes 4 are formed on a bottom side surface of the uppermost semiconductor device 3 as well, and these electrodes 4 are joined via a brazing material layer 40 to the top of the plug portions 36 on the semiconductor device 1 underneath each, and the gaps therein are then filled with underfill resin 63.

Here, when stacking another semiconductor device 1 on top of a semiconductor device 1, firstly, flux (not shown) is coated either on top of the plug portions 36 of the electrodes 34 of the lower device 1 or on the brazing material layer 40 of the post portions 35 of the electrodes 34 of the upper device 1, thereby achieving an improvement in the wettability of the brazing material (i.e., the solder). Next, the semiconductor devices 1 are positioned such that the post portions 35 of the electrodes 34 of the upper device 1 are in contact via the brazing material layer 40 and the flux with the plug portions 36 of the electrodes 34 of the lower device 1. Next, reflow boding using heat or else flip-chip packaging using thermal compression is performed, thereby melting and then curing the brazing material (i.e., the solder) of the brazing material layer 40. As a result, the plug portions 36 on the lower side are brazed, namely, soldered to the post portions 35 on the upper side.

At this time, because both the plug portions 36 and the post portions 35 protrude beyond the surface of the semiconductor substrate 10, matching the positions of each is simplified, and they can be easily bonded by providing the brazing material layer 40 on the protruding portions.

Moreover, because the outer diameter (i.e., the size) of the post portions 35, in particular, is larger than the outer diameter of the first insulating film 22 that covers the protruding portion of the plug portions 36, the brazing material (i.e., the solder) is more easily bonded to the outer surfaces of these. In addition, because the wettability between the bonded brazing material and the surfaces is improved thereby improving the bonding strength. As a result, bonds between electrodes 34 can be made strong and reliable. In contrast, because the plug portions 36 protrude still further beyond the first insulating film 22 so that side surfaces thereof are exposed, brazing material (i.e., solder) can be wetted more easily and bonded more easily to these protruding and exposed side surfaces.

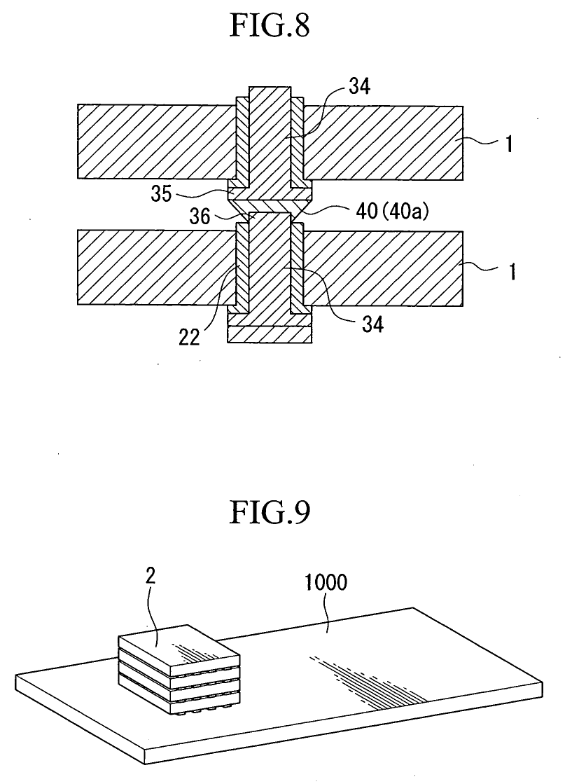

Accordingly, because the brazing material (solder) is more easily wetted and more easily bonded to both the post portions 35 and the plug portions 36, the brazing material (solder) is more firmly bonded to the electrodes 34 to form fillets 40a, thereby enabling more high strength bonding to be performed. Moreover, because the brazing material (solder), in particular, has a fillet 40a structure such as that shown in FIG. 8, namely, a tapered configuration that covers portions from the outer surface of the post portions 35 towards protruding, exposed side surfaces of the plug portions 36, a large surface area of each is bonded. As a result, the semiconductor device 2 shown in FIG. 7 has a stacked structure that has greater resistance to shearing force acting on the semiconductor devices 1.

Furthermore, on the plug portion 36 side, in particular, because the brazing material (solder) is more easily wetted on side surfaces of the protruding, exposed plug portion 36 than on the first insulating film 22 that covers the plug portion 36, the brazing material (solder) is selectively bonded to these side surfaces. Accordingly, the brazing material (solder) is not wetted on the first insulating film 22 and bonded thereto. Accordingly, it is possible to prevent problems such as this brazing material (solder) extending to and touching the rear surface 10b of the semiconductor substrate 10, and thereby causing a short circuit to occur.

Note that, as described above, if the second insulating film 26 is formed on the rear surface 10b of the semiconductor substrate 10, it is possible to more reliably prevent short circuits caused by this type of contact by the brazing material (solder).

Next, examples of a circuit substrate and electronic instrument provided with the above described semiconductor device 2 will be described.

FIG. 9 is a perspective view showing the schematic structure of an embodiment of the circuit substrate of the present invention. As is shown in FIG. 9, the above described semiconductor device 2 is mounted on a circuit substrate 1000 of this embodiment. The circuit substrate 1000 is formed, for example, by an organic based substrate such as a glass epoxy substrate, and is formed, for example, such that a wiring pattern (not shown) made of copper or the like forms a predetermined circuit, and electrode pads (not shown) are connected to this wiring pattern. By then connecting the solder balls 62 of the interposer substrate 60 of the semiconductor device 2 to these electric pads, the semiconductor device 2 is packaged on the circuit substrate 1000. Here, the packaging of the semiconductor device 2 on the circuit substrate 1000 is performed by connecting the solder balls 62 of the interposer substrate 60 to the electrode pads on the circuit substrate 1000 side using a reflow method or flip-chip bonding method.

Because a semiconductor device 2 having a high packaging density is provided in the circuit substrate 1000 having this type of structure, reductions in both size and weight can be achieved, and the wiring connections are also extremely reliable.

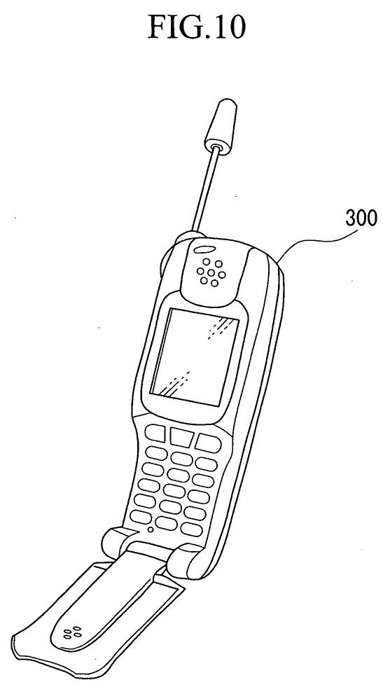

FIG. 10 is a perspective view showing the schematic structure of a mobile telephone serving as an embodiment of the electronic instrument of the present invention. As is shown in FIG. 10, the mobile telephone 300 has the semiconductor devices 2 or the circuit substrates 1000 provided inside housings thereof.

Because a semiconductor device 2 having a high packaging density is provided in the mobile telephone 300 (i.e., electronic instrument) having this type of structure, reductions in both size and weight can be achieved, and the wiring connections are also extremely reliable.

Note that, the electronic instrument is not limited to the aforementioned mobile telephone and the present invention may be applied to a variety of electronic instruments. For example, the present invention may be applied to electronic instruments such as notebook computers, liquid crystal projectors, personal computers (PC) and engineering work stations (EWS) for dealing with multimedia, pagers, word processors, televisions, viewfinder type or direct view monitor type of video tape recorders, electronic diaries, electronic desktop calculators, car navigation systems, POS terminals, and devices provided with touch panels.

It is to be understood that the technological range of the present invention is not limited to the above embodiments and other design modifications may be included as long as they do not depart from the spirit or scope of the present invention. Specific materials and layer structures and the like described in the above embodiments are merely examples and may be modified as is considered appropriate.

What is claimed is:

1. A semiconductor device comprising:
a semiconductor substrate with a through hole formed therein;
a first insulating film formed on an inner wall of said through hole; and
an electrode formed on an inner side of said first insulating film inside said through hole, wherein
said first insulating film at a rear surface side of said semiconductor substrate protrudes beyond said rear surface, and
said electrode protrudes on both an active surface side and said rear surface side of said semiconductor substrate, and an outer diameter of a protruding portion of said electrode on said active surface side is larger than an outer diameter of said first insulating film inside said through hole, and a protruding portion of said electrode on said rear surface side protrudes further beyond said first insulating film so as to have a side surface thereof exposed.

2. A semiconductor device comprising:
a plurality of semiconductor devices according to claim 1 that are stacked vertically with an active surface side of one semiconductor substrate facing a rear surface side of another semiconductor substrate, wherein
a protruding portion of an electrode of one semiconductor device of said plurality of semiconductor devices is electrically connected by brazing material to a protruding portion of an electrode of another semiconductor device of said plurality of semiconductor devices, and wherein
said brazing material forms a fillet that bonds from an outer surface of said protruding portion of said electrode of said one semiconductor device on said active surface side of said one semiconductor substrate to a side surface of said protruding portion of said electrode of said another semiconductor device on said rear surface side of said another semiconductor substrate, said side surface protruding beyond said first insulating film and being exposed.

3. The semiconductor device according to claim 1, further comprising a second insulating film that covers at least peripheral portions of said electrode on said rear surface side of said semiconductor substrate, and said electrode protrudes beyond said second insulating film such that at least a portion of a side surface of said electrode is exposed.

4. The semiconductor device according to claim 2, further comprising a second insulating film that covers at least peripheral portions of said electrode on said rear surface side of said semiconductor substrate, and said electrode protrudes beyond said second insulating film such that at least a portion of a side surface of said electrode is exposed.

5. The semiconductor device according to claim 1, further comprising a barrier layer provided between said first insulating film and said electrode such that electrode material is prevented from spreading to said semiconductor substrate.

6. The semiconductor device according to claim 2, further comprising a barrier layer provided between said first insulating film and said electrode such that electrode material is prevented from spreading to said semiconductor substrate.

7. The semiconductor device according to claim 3, further comprising a barrier layer provided between said first insulating film and said electrode such that electrode material is prevented from spreading to said semiconductor substrate.

8. The semiconductor device according to claim 4, further comprising a barrier layer provided between said first insulating film and said electrode such that electrode material is prevented from spreading to said semiconductor substrate.

9. A circuit substrate comprising the semiconductor device according to claim 1.

10. An electronic instrument comprising the semiconductor device according to claim 1.
